(19) United States
(12) Patent Application Publication
(10) Pub. No.: US 2024/0237566 A1
(43) Pub. Date: Jul. 11, 2024

(54) ARTIFICIAL SYNAPSE DEVICE BASED ON RESISTIVE CHANGE MEMORY DEVICE, AND METHOD FOR MANUFACTURING SAME

(71) Applicant: IUCF-HYU (Industry-University Cooperation Foundation Hanyang University), Seoul (KR)

(72) Inventors: Jea Gun PARK, Seoul (KR); Dae Seong WOO, Seoul (KR); Soo Min JIN, Seoul (KR); Sang Hong PARK, Seoul (KR); Sung Mok JUNG, Seoul (KR)

(21) Appl. No.: 18/443,283

(22) Filed: Feb. 15, 2024

Related U.S. Application Data
(63) Continuation of application No. PCT/KR2022/012483, filed on Aug. 22, 2022.

(30) Foreign Application Priority Data
Aug. 23, 2021 (KR) 10-2021-0110991

(51) Int. Cl. H10N 70/00; G06N 3/063; H10B 63/00; H10N 70/20

(52) U.S. Cl. CPC H10N 70/8845; G06N 3/063; H10B 63/80; H10N 70/026; H10N 70/24; H10N 70/841

(57) ABSTRACT

Disclosed is an artificial synapse device including an amorphous carbon oxide-based resistance change memory device and a method of fabricating the same, and more particularly to a technology for providing an artificial synapse device capable of implementing the characteristics of biological synapses responsible for memory and information transfer in the human brain using a resistance change memory device. More particularly, the artificial synapse device according to an embodiment of the provided includes a first electrode; a second electrode disposed to face the first electrode; and a switching layer formed of an amorphous carbon oxide deposited by injecting oxygen when sputtering carbon into a target between the first electrode and the second electrode, wherein the artificial synapse device has synaptic characteristics wherein a value of an output current changes gradually when a same voltage of either set voltage or reset voltage is repeatedly applied to the first electrode.

### TECHNICAL FIELD

The present invention relates to an artificial synapse device including an amorphous carbon oxide-based resistance change memory device and a method of fabricating the same, and more particularly to a technology for providing an artificial synapse device capable of implementing the characteristics of biological synapses responsible for memory and information transfer in the human brain using a resistance change memory device.

### BACKGROUND ART

All computers in use today adopt the von Neumann architecture.

The von Neumann structure according to the prior art is separated into a Central Processing Unit (CPU) and memory, and reads instructions or reads and writes data through a bus for connecting the two components.

Due to the design that separates the roles of CPU and memory, today's computers have the great advantage of being able to process various data using only software without changing hardware.

However, the von Neumann architecture has a fatal drawback in that the bandwidth between the CPU and memory is low.

That is, since program memory and data memory interact with CPU through one bus without physical distinction, the CPU cannot access instructions and data at the same time, and the bottleneck that listed instructions are read and written one at a time inevitably occurs.

Deep learning, which has recently attracted attention in the field of artificial intelligence, requires large-scale parallel processing, and implementing deep learning by applying the von Neumann architecture reduces efficiency in terms of data processing, transmission speed, and energy consumption.

Therefore, the neuromorphic architecture, which has hardware that mimics the human brain's neural structure, is being presented as a new alternative.

The neuromorphic architecture consists of elements that play the role of neurons, which are nerve cells in the brain; and elements that play the role of biological synapse that exists between neurons.

This structure is capable of parallel computing, allowing large amounts of memory and computation to be carried out simultaneously.

Recently, active research has been conducted on hardware-based artificial synapses that can mimic the functions of synapses.

The human brain has about 100 billion neurons and 100 trillion synapses connected in parallel.

Each neuron receives input signals from other neurons through dendrites and sends signals to other neurons through axons.

At this time, the synapse plays a role in connecting neurons and plays an important role in determining how much weight to transmit signals received from the axons of other neurons.

When mimicking the characteristics of long-term potentiation/long-term depression which are characteristics of biological synapses, using an oxide-based memristor, the synapse weight tends to increase or decrease linearly, symmetrically, and gradually when a certain pulse is continuously applied.

In the prior art, there is research on implementing neuromorphic chips using SRAM-based cross point array cells.

However, the conventional SRAM-based cross point array cell basically consists of 8 transistors, which has the fatal disadvantage of being very disadvantageous in terms of integration.

In addition, an artificial synapse device with a three-terminal structure, which is based on an ion-doped electrolyte and a reduced graphene oxide, disclosed by a research team at Pohang University of Science and Technology in 2020 has the disadvantage of being difficult to commercialize because it is not compatible with the Complementary Metal-Oxide Semiconductor (CMOS) process and is based on a solution process and thus does not utilize vacuum equipment.

### DISCLOSURE

### Technical Problem

Therefore, the present invention has been made in view of the above problems, and it is one object of the present invention to provide an artificial synapse device configured to implement the characteristics of biological synapses, which are responsible for memory and information transfer in the human brain, using a resistance change memory device.

It is another object of the present invention to provide an artificial synapse device that allows fine weight adjustments during online learning on Modified National Institute of Standards and Technology (MINIST) handwriting images by securing multiple conductivity levels.

It is still another object of the present invention to provide a 2-terminal artificial synapse device while utilizing a Complementary Metal-Oxide Semiconductor (CMOS) process, thereby being capable of addressing an integration problem and a CMOS process compatibility problem.

It is still another object of the present invention to provide an artificial synapse device with multiple conductivity levels corresponding to 32 levels using an amorphous carbon oxide-based resistance change memory device.

It is still another object of the present invention to provide an artificial synapse device array including a plurality of artificial synapse devices that maintain multiple conductivity levels corresponding to 32 levels using a plurality of resistance change memory devices based on an amorphous carbon oxide.

It is yet another object of the present invention to improve the mass productivity of an artificial synapse device by using an on-axis sputtering process.

### Technical Solution

In accordance with an aspect of the present invention, the above and other objects can be accomplished by the provision of an artificial synapse device, including: a first electrode;
a second electrode disposed to face the first electrode; and
a switching layer formed of an amorphous carbon oxide deposited by injecting oxygen when sputtering carbon into a target between the first electrode and the second electrode,
wherein the artificial synapse device has synaptic characteristics wherein a value of an output current changes gradually when a same voltage of either set voltage or reset voltage is repeatedly applied to the first electrode.

The artificial synapse device may have multiple conductivity levels as the value of the output current gradually increases when a set voltage with a same pulse width, pulse interval, and voltage magnitude is repeatedly applied to the first electrode.

The artificial synapse device may have multiple conductivity levels as the value of the output current gradually reduces when a reset voltage with a same pulse width, pulse interval, and voltage magnitude is repeatedly applied to the first electrode.

The artificial synapse device may perform one memory operation of a short-term memory operation wherein a current value is reduced to an initial value after a certain time based on the number of times the same voltage is repeatedly applied and a long-term memory operation wherein the current value is maintained after the certain time.

The switching layer may be formed of the amorphous carbon oxide deposited by injecting oxygen in an oxygen content of 10% to 11% based on an on-axis sputtering process when sputtering the carbon to a target.

Oxygen atoms, oxygen ions, oxygen vacancies, first hybrid orbitals (C—C sp²) of carbon atoms and second hybrid orbitals (C—C sp³) of carbon atoms may coexist in a pristine state of the switching layer, and, when the set voltage is applied to the first electrode, filaments of oxygen vacancies and filaments of first hybrid orbitals (C—C sp²) may be formed between the first electrode and the second electrode, thereby becoming a set state of a low-resistance state (LRS).

In the switching layer when the set voltage is applied to the first electrode, a binding ratio of the first hybrid orbitals (C—C sp²) may increase while the oxygen ions move toward the second electrode, and filaments of the oxygen vacancies and filaments of the first hybrid orbitals (C—C sp²) may be formed as a binding ratio of the second hybrid orbitals (C—C sp³) and a binding ratio of the oxygen atoms and the carbon atoms decrease.

In the switching layer when the reset voltage is applied to the first electrode in the set state, the filaments of the oxygen vacancies and the filaments of the first hybrid orbitals (C—C sp²) between the first electrode and the second electrode may be broken, becoming a reset state of a high-resistance state (HRS).

In the switching layer when the reset voltage is applied to the first electrode, the filaments of the oxygen vacancies and the filaments of the first hybrid orbitals (C—C sp²) may be broken as the oxygen ions move toward the first electrode, the binding ratio of the first hybrid orbitals (C—C sp²) decreases, and the binding ratio of the second hybrid orbitals (C—C sp³) and the binding ratio of the oxygen atoms and the carbon atoms increase.

The first electrode and the second electrode may be formed of at least one metal material selected from platinum (Pt), tungsten (W), titanium nitride (TiN), tantalum nitride (TaN), gold (Au), rubidium (Ru), iridium (Ir), palladium (Pd), titanium (Ti), hafnium (Hf), molybdenum (Mo) and niobium (Nb).

In accordance with another aspect of the present invention, there is provided a method of fabricating an artificial synapse device, the method including: forming a second electrode on a substrate, forming a switching layer with an amorphous carbon oxide deposited by injecting oxygen when sputtering carbon to a target on the second electrode, and forming a first electrode on the switching layer to form the artificial synapse device, the artificial synapse device has synaptic characteristics wherein a value of an output current changes gradually when a same voltage of either set voltage or reset voltage is repeatedly applied to the first electrode.

The artificial synapse device may have multiple conductivity levels as the output current value gradually increases when a set voltage with a same pulse width, pulse interval, and voltage magnitude is repeatedly applied to the first electrode or multiple conductivity levels as the output current value gradually reduces when a reset voltage with a same pulse width, pulse interval, and voltage magnitude is repeatedly applied to the first electrode.

The artificial synapse device may perform one memory operation of a short-term memory operation wherein a current value is reduced to an initial value after a certain time based on the number of times the same voltage is repeatedly applied and a long-term memory operation wherein the current value is maintained after the certain time.

The forming of the switching layer may include forming a switching layer with the amorphous carbon oxide deposited by injecting oxygen in an oxygen content of 10% to 11% based on an on-axis sputtering process when sputtering the carbon to the target.

In accordance with yet another aspect of the present invention, there is provided an artificial synapse device array, including: a plurality of artificial synapse devices, each of the artificial synapse devices including a first electrode, a second electrode disposed to face the first electrode, and a switching layer formed of an amorphous carbon oxide deposited by injecting oxygen when sputtering carbon to a target between the second electrode; a plurality of word lines connected to a first electrode of each of the plural artificial synapse devices; and a plurality of bit lines connected to a second electrode of each of the plural artificial synapse devices, wherein each of the plural artificial synapse devices has synaptic characteristics wherein a value of an output current changes gradually when a same voltage of either set voltage or reset voltage is repeatedly applied to the first electrode through each of the plural word lines.

Each of the artificial synapse devices may have multiple conductivity levels as the value of the output current gradually increases when a set voltage with a same pulse width, pulse interval, and voltage magnitude is repeatedly applied to the first electrode through each of the plural word lines or multiple conductivity levels as the value of the output current gradually reduces when a reset voltage with a same pulse width, pulse interval, and voltage magnitude is repeatedly applied to the first electrode through each of the plural word lines.

### Advantageous Effects

As apparent above, the present invention can provide an artificial synapse device configured to implement the characteristics of biological synapses, which are responsible for memory and information transfer in the human brain, using a resistance change memory device.

The present invention can provide an artificial synapse device that allows fine weight adjustments during online learning on Modified National Institute of Standards and Technology (MINIST) handwriting images by securing multiple conductivity levels.

The present invention provides a 2-terminal artificial synapse device while utilizing a Complementary Metal-Oxide Semiconductor (CMOS) process, thereby being capable of addressing an integration problem and a CMOS process compatibility problem.

The present invention can provide an artificial synapse device with multiple conductivity levels corresponding to 32 levels using an amorphous carbon oxide-based resistance change memory device.

The present invention can provide an artificial synapse device array including a plurality of artificial synapse devices that maintain multiple conductivity levels corresponding to 32 levels using a plurality of resistance change memory devices based on an amorphous carbon oxide.

The present invention can improve the mass productivity of an artificial synapse device by using an on-axis sputtering process.

### DESCRIPTION OF DRAWINGS

FIG. 1 is a drawing for explaining an artificial synapse device according to an embodiment of the present invention.

FIGS. 2A to 2C are drawings for explaining the switching mechanism of the artificial synapse device according to an embodiment of the present invention.

FIGS. 3A to 3C are drawings for explaining XPS C1s peak according to an etching time of the artificial synapse device according to an embodiment of the present invention.

FIG. 4 is a drawing for explaining the switching model of the artificial synapse device according to an embodiment of the present invention.

FIGS. 5A and 5B are drawings for explaining a process of fabricating the artificial synapse device according to an embodiment of the present invention.

FIG. 6A is a drawing for explaining the crossbar structure of the artificial synapse device according to an embodiment of the present invention.

FIGS. 6B to 6D are drawings for explaining the electrical characteristics of the crossbar structure of the artificial synapse device according to an embodiment of the present invention.

FIGS. 7A to 7C are drawings for explaining the paired-pulse facilitation (PPF) characteristics and memory characteristics of the artificial synapse device according to an embodiment of the present invention.

FIGS. 8A and 8B are drawings for explaining the electrical characteristics according to the gradual set or reset process of the artificial synapse device according to an embodiment of the present invention.

FIGS. 9A and 9B are drawings for explaining the synaptic characteristics of the artificial synapse device according to an embodiment of the present invention.

FIGS. 10A and 10B are drawings for explaining an artificial neuron network using the artificial synapse device according to an embodiment of the present invention and the recognition rate of the artificial neuron network.

FIG. 11 illustrates a drawing for explaining an artificial synapse device array using a plurality of artificial synapse devices according to an embodiment of the present invention.

### BEST MODE

The present invention will now be described more fully with reference to the accompanying drawings, in which exemplary embodiments of the invention are shown.

This invention, however, should not be construed as limited to the exemplary embodiments and terms used in the exemplary embodiments, and should be understood as including various modifications, equivalents, and substituents of the exemplary embodiments.

Preferred embodiments of the present invention are now described more fully with reference to the accompanying drawings. In the description of embodiments of the present invention, certain detailed explanations of related known functions or constructions are omitted when it is deemed that they may unnecessarily obscure the essence of the invention.

In addition, the terms used in the specification are defined in consideration of functions used in the present invention, and can be changed according to the intent or conventionally used methods of clients, operators, and users. Accordingly, definitions of the terms should be understood on the basis of the entire description of the present specification.

In the drawings, like reference numerals in the drawings denote like elements.

As used herein, the singular forms “a,” “an” and “the” are intended to include the plural forms as well, unless context clearly indicates otherwise.

Expressions such as “A or B” and “at least one of A and/or B” should be understood to include all possible combinations of listed items.

Expressions such as “a first,” “the first,” “a second” and “the second” may qualify corresponding components irrespective of order or importance and may be only used to distinguish one component from another component without being limited to the corresponding components.

In the case in which a (e.g., first) component is referred as “(functionally or communicatively) connected” or “attached” to another (e.g., second) component, the first component may be directly connected to the second component or may be connected to the second component via another component (e.g., third component).

In the specification, the expression “ . . . configured to . . . (or set to)” may be used interchangeably, for example, with expressions, such as “ . . . suitable for . . . ,” “ . . . having ability to . . . ,” “ . . . modified to . . . ,” “ . . . manufactured to . . . ,” “ . . . enabling to . . . ,” “ . . . designed to . . . ,” in the case of hardware or software depending upon situations.

In any situation, the expression “a device configured to . . . ” may refer to a device configured to operate “with another device or component.”

For examples, the expression “a processor configured (or set) to execute A, B, and C” may refer to a specific processor performing a corresponding operation (e.g., embedded processor), or a general-purpose processor (e.g., CPU or application processor) executing one or more software programs stored in a memory device to perform corresponding operations.

In addition, the expression “or” means “inclusive or” rather than “exclusive or”.

That is, unless otherwise mentioned or clearly inferred from context, the expression “x uses a or b” means any one of natural inclusive permutations.

In the aforementioned embodiments, constituents of the present invention were expressed in a singular or plural form depending upon embodiments thereof.

However, the singular or plural expressions should be understood to be suitably selected depending upon a suggested situation for convenience of description, and the aforementioned embodiments should be understood not to be limited to the disclosed singular or plural forms. In other words, it should be understood that plural constituents may be a singular constituent or a singular constituent may be plural constituents.

While the embodiments of the present invention have been described, those skilled in the art will appreciate that many modifications and changes can be made to the present invention without departing from the spirit and essential characteristics of the present invention.

Therefore, it should be understood that there is no intent to limit the disclosure to the embodiments disclosed, rather, the disclosure is to cover all modifications, equivalents, and alternatives falling within the spirit and scope of the disclosure as defined by the claims.

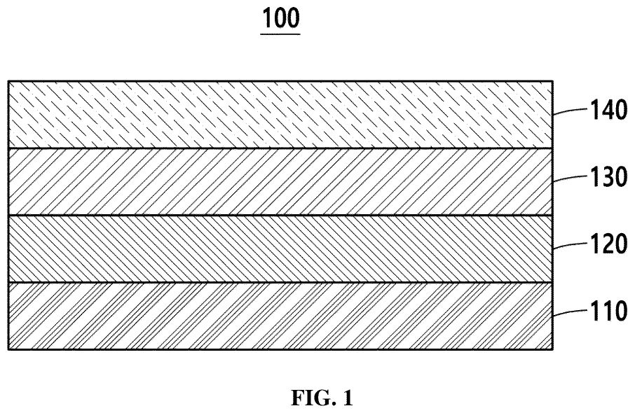

FIG. 1 is a drawing for explaining an artificial synapse device according to an embodiment of the present invention.

FIG. 1 illustrates the structure of the artificial synapse device according to an embodiment of the present invention.

Referring to FIG. 1, an artificial synapse device 100 according to an embodiment of the present invention includes a substrate 110, a second electrode 120, a switching layer 130 and a first electrode 140.

For example, the artificial synapse device 100 includes the first electrode 140, the second electrode 120 disposed to face the first electrode 140, and the switching layer 130 formed between the first electrode 140 and the second electrode 120 and formed of an amorphous carbon oxide deposited by injecting oxygen when sputtering carbon to a target.

For example, the artificial synapse device 100 may be a resistance change memory device in which the resistance state of the switching layer 130 is changed based on a set voltage corresponding to a negative voltage applied through the first electrode 140 or a reset voltage corresponding to a positive voltage applied through the first electrode 140.

For example, the substrate 110 may be a silicon (SiO₂) substrate.

The artificial synapse device 100 according to an embodiment of the present invention may have the synapse characteristic wherein the value of an output current gradually changes when the same voltage of either a set voltage or a reset voltage is repeatedly applied to the first electrode 140.

For example, the artificial synapse device 100 may have multiple conductivity levels as the value of the output current gradually increases when a set voltage with the same pulse width, pulse interval, and voltage magnitude is repeatedly applied to the first electrode 140.

The artificial synapse device 100 according to an embodiment of the present invention may have multiple conductivity levels as the value of the output current gradually reduces when a reset voltage with the same pulse width, pulse interval, and voltage magnitude is repeatedly applied to the first electrode 140.

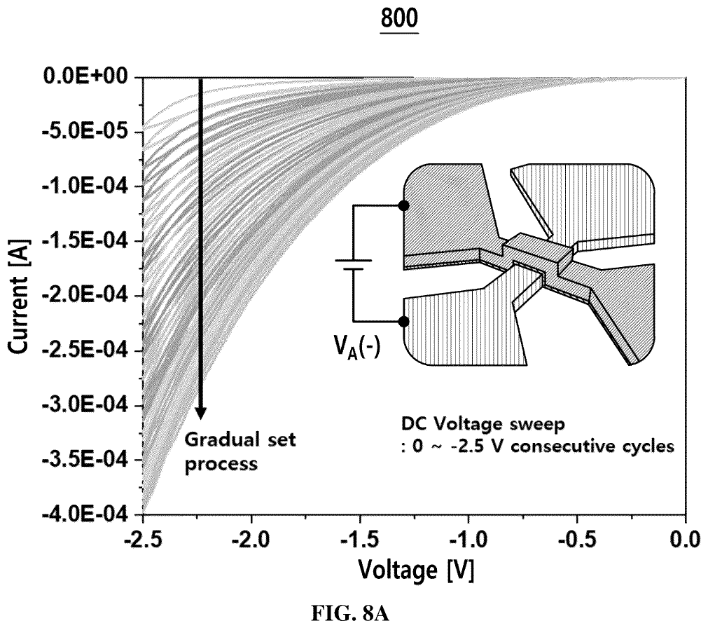

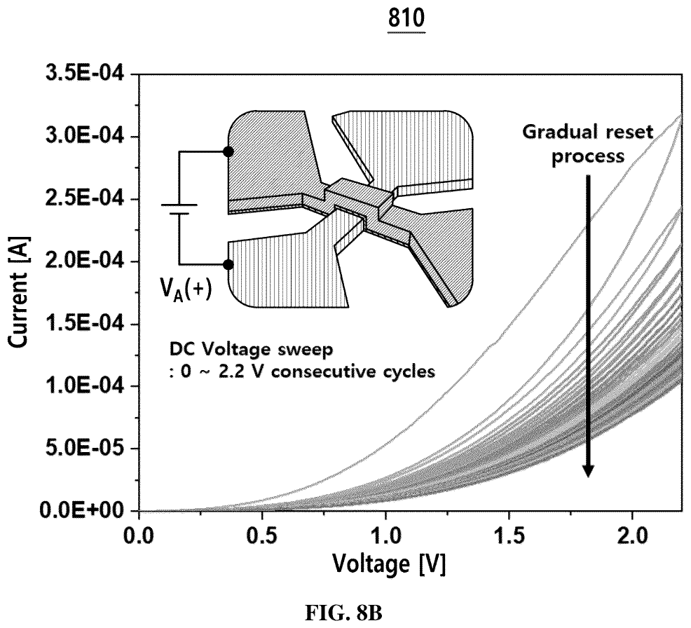

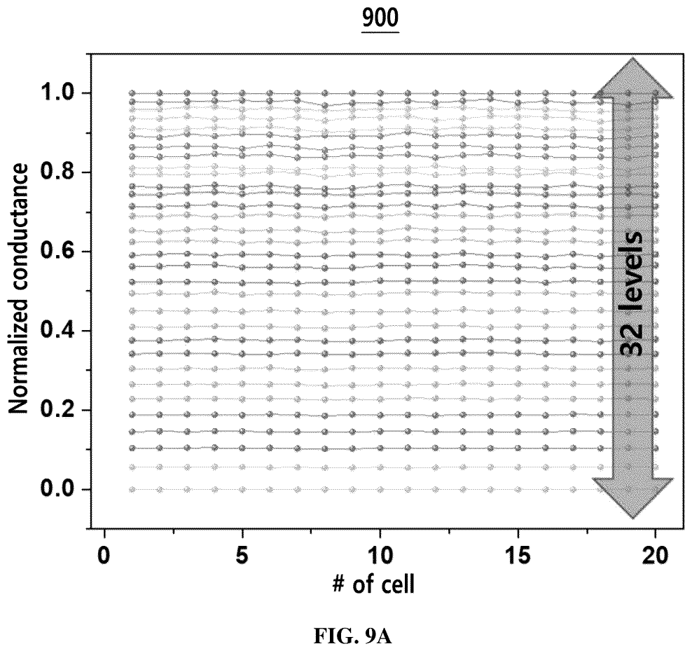

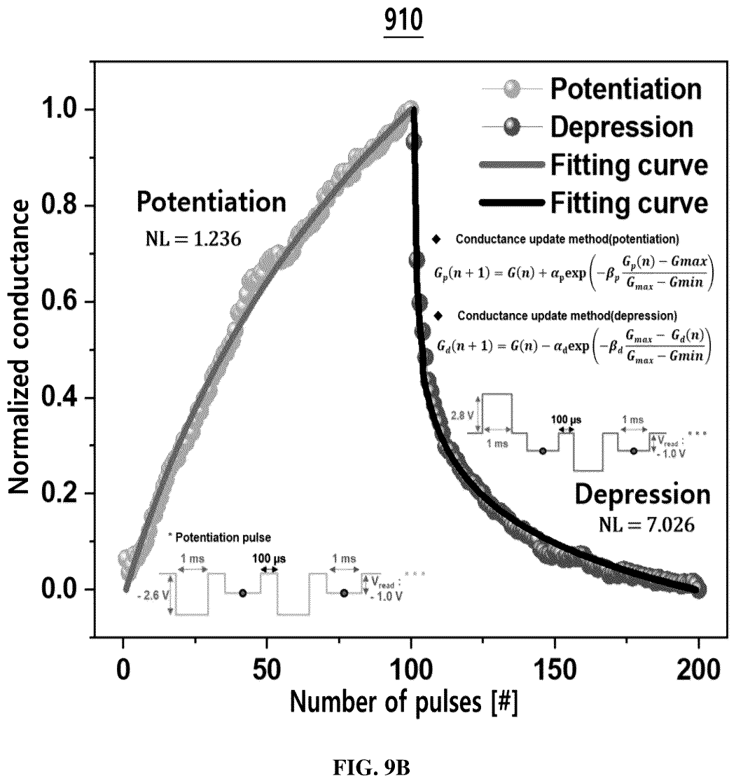

Supplementary explanations of the multiple conductivity levels of the artificial synapse device 100 will be given when describing FIGS. 8A to 9B.

For example, the artificial synapse device 100 may perform one memory operation of a short-term memory operation wherein a current value is reduced to an initial value after a certain time based on the number of times the same voltage is repeatedly applied and a long-term memory operation wherein the current value is maintained after the certain time.

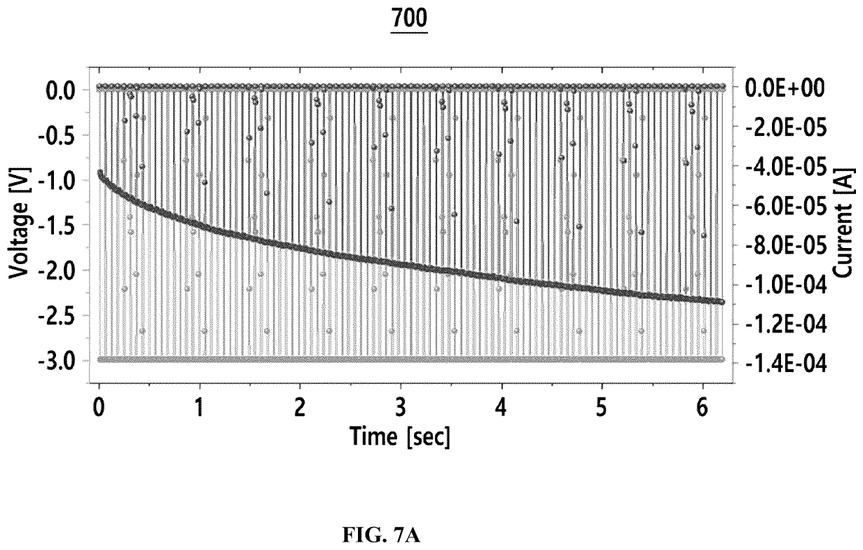

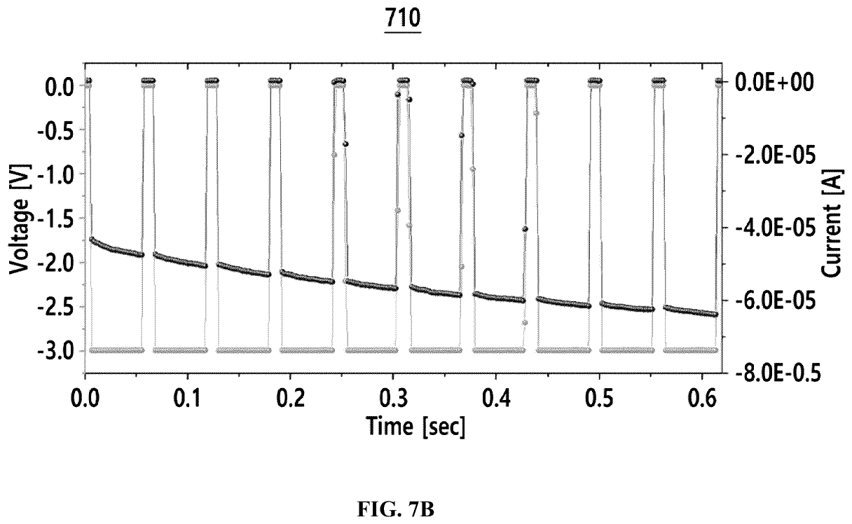

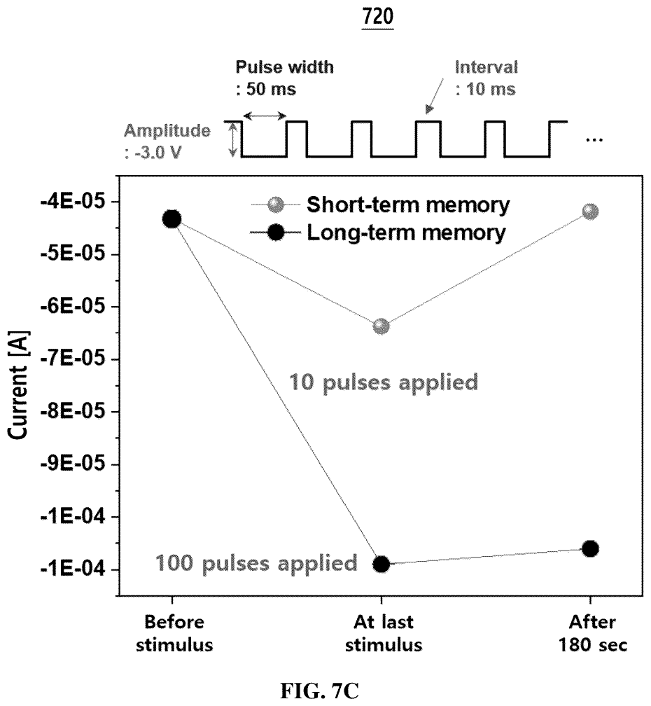

Supplementary explanations of the short-term memory operation and long-term memory operation of the artificial synapse device 100 will be given when describing FIG. 7C.

According to an embodiment of the present invention, the switching layer 130 may be formed of an amorphous carbon oxide deposited by injecting oxygen in an oxygen content of 10% to 11% based on an on-axis sputtering process when sputtering carbon to a target.

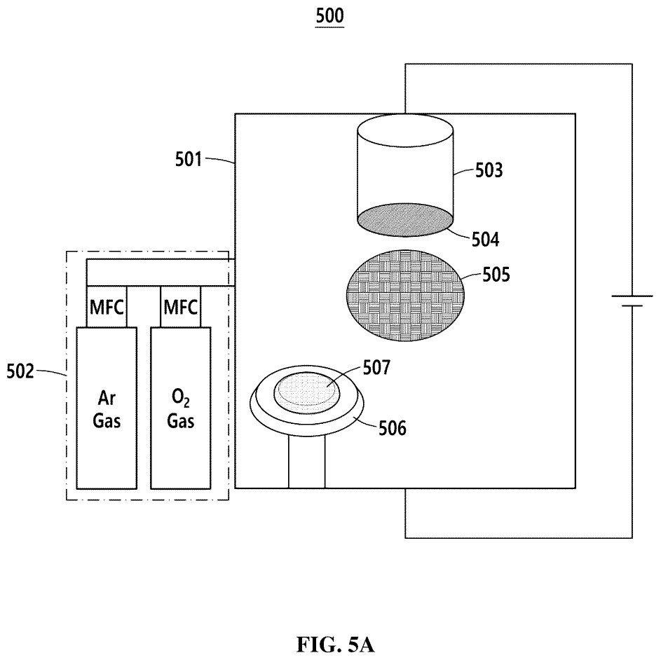

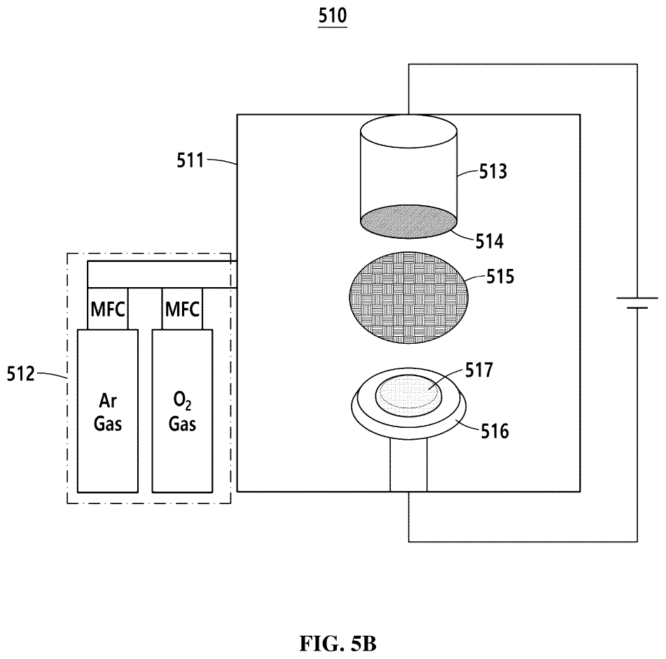

For example, according to an embodiment of the present invention, the switching layer 130 is formed based on an on-axis sputtering process rather than an off-axis sputtering process. Supplementary explanations of this on-axis sputtering process will be given when describing FIGS. 5A and 5B.

According to an embodiment of the present invention, the switching layer 130 may be determined to be in a set state or reset state based on the set voltage or reset voltage applied through the first electrode 140.

For example, the set state may be a low-resistance state (LRS), and the reset state may be a high-resistance state (HRS).

For example, oxygen atoms, oxygen ions, oxygen vacancies, first hybrid orbitals (C—C sp²) of carbon atoms and second hybrid orbitals (C—C sp³) of carbon atoms coexist in a pristine state of the switching layer 130, and, when the set voltage is applied to the first electrode 140, filaments of oxygen vacancies and filaments of first hybrid orbitals (C—C sp²) are formed between the first electrode 140 and the second electrode 120, thereby becoming a set state of a low-resistance state (LRS).

According to an embodiment of the present invention, the switching layer 130 may become a reset state of a high-resistance state (HRS) as filaments of oxygen vacancies and filaments of first hybrid orbitals (C—C sp²) between the first electrode 140 and the second electrode 120 are broken when reset voltage is applied to the first electrode 140 in a set state.

According to an embodiment of the present invention, the first electrode 140 and the second electrode 120 may be formed of at least one metal material selected from platinum (Pt), tungsten (W), titanium nitride (TiN), tantalum nitride (TaN), gold (Au), rubidium (Ru), iridium (Ir), palladium (Pd), titanium (Ti), hafnium (Hf), molybdenum (Mo) and niobium (Nb).

Preferably, the first electrode 140 may be formed of platinum (Pt), and the second electrode 120 may be formed of tungsten (W).

The artificial synapse device 100 according to an embodiment of the present invention may be produced by a method of fabricating an artificial synapse device.

For example, the method of fabricating an artificial synapse device may include a step of forming the second electrode 120 on the substrate 110, a step of forming the switching layer 130 with an amorphous carbon oxide deposited by injecting oxygen when sputtering carbon to a target on the second electrode 120, and a step of forming the first electrode 140 on the switching layer 130 to form the artificial synapse device 100.

In addition, the method of fabricating an artificial synapse device utilizes a Complementary Metal-Oxide Semiconductor (CMOS) process.

Therefore, the present invention can provide an artificial synapse device that implements the characteristics of biological synapses, responsible for memory and information transfer in the human brain, using a resistance change memory device according to one embodiment.

In addition, the present invention utilizes the Complementary Metal-Oxide Semiconductor (CMOS) process and provides an artificial synapse device of a 2-terminal, thereby solving an integration problem and a CMOS process compatibility problem.

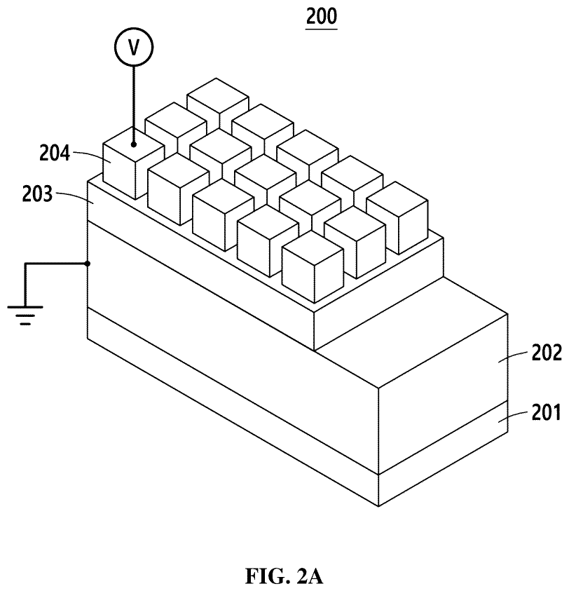

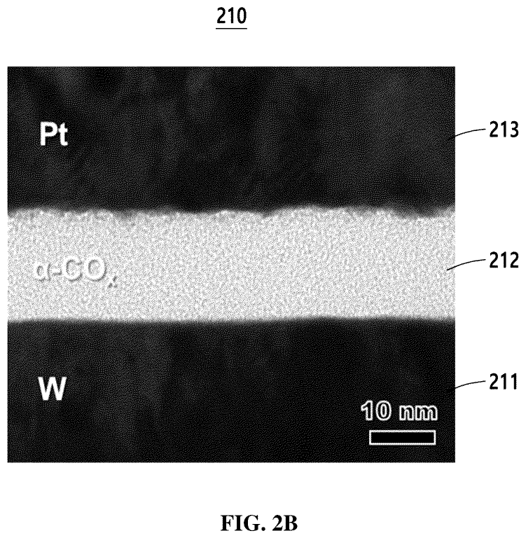

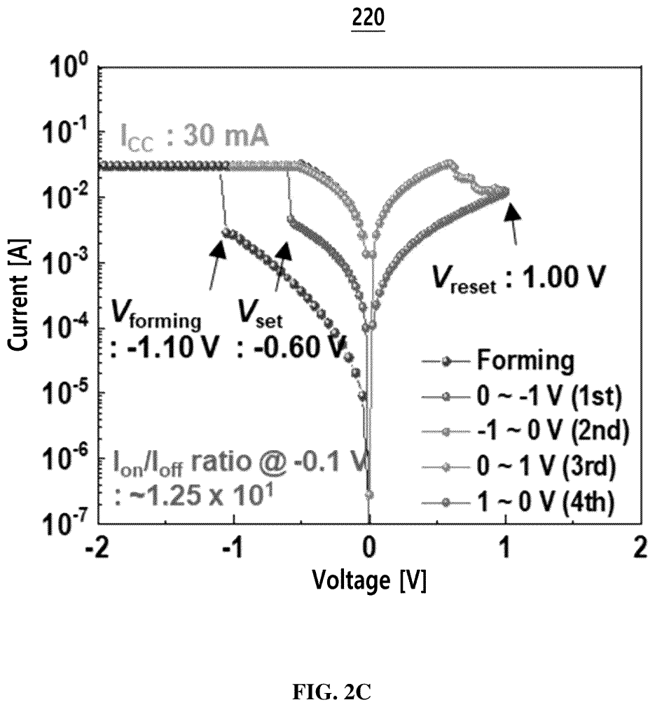

FIGS. 2A to 2C are drawings for explaining the switching mechanism of the artificial synapse device according to an embodiment of the present invention.

FIGS. 2A to 2C illustrate an example of an experimental structure for analyzing the switching mechanism of the artificial synapse device according to an embodiment of the present invention by changing the cell size of memory.

FIG. 2A illustrates an experimental structure for analyzing the operation mechanism of the artificial synapse device according to an embodiment of the present invention.

Referring to FIG. 2A, an artificial synapse device 200 according to an embodiment of the present invention includes a substrate 201, a second electrode 202, a switching layer 203 and a first electrode 204.

according to an embodiment of the present invention, the first electrode 204 is formed of platinum (Pt) and applied with set voltage and reset voltage.

For example, the second electrode 202 is formed of tungsten (W) and connected to the ground.

The switching layer 203 according to an embodiment of the present invention may be formed of an oxygenated amorphous carbon oxide deposited between the first electrode 204 and the second electrode 202 using physical vapor deposition of sputtering carbon while injecting oxygen into a target.

For example, the artificial synapse device 200 may have a memory cell size of 60×60 μm².

FIG. 2B illustrates a transmission electron microscope image of an experimental structure for analyzing the operation mechanism of the artificial synapse device according to an embodiment of the present invention.

Referring to a transmission electron microscope image 210 of FIG. 2B, in the artificial synapse device according to an embodiment of the present invention, the second electrode 211 is formed of tungsten (W), the switching layer 212 is formed of an amorphous carbon oxide (α-COₓ), and the first electrode 213 is formed of platinum (Pt).

That is, the artificial synapse device according to an embodiment of the present invention may be formed in a platinum/amorphous carbon oxide/tungsten structure.

FIG. 2C is a drawing for explaining operation characteristics in an experimental structure of a resistance change memory device according to an embodiment of the present invention.

Referring to graph 220 of FIG. 2C, it can be confirmed that the artificial synapse device according to the experimental structure illustrated in FIGS. 2A and 2B has electrical characteristics characterized by operating under a forming voltage of −1.10 V, operating under a set voltage of −0.60 V, and operating under a reset voltage of +1.00 V at a memory cell size of 60×60 μm² and having a memory margin (Ion/Ioff) of 1.25×10¹.

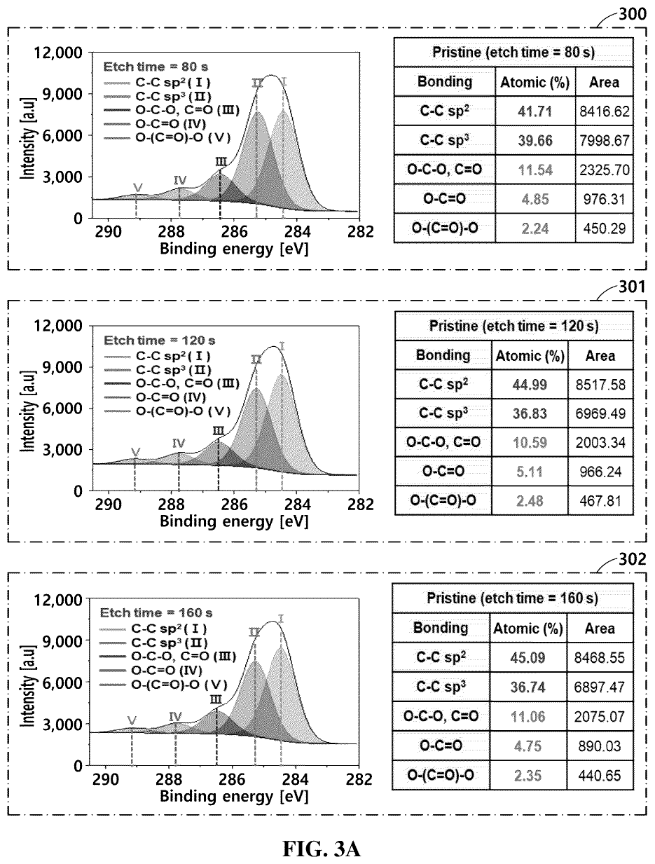

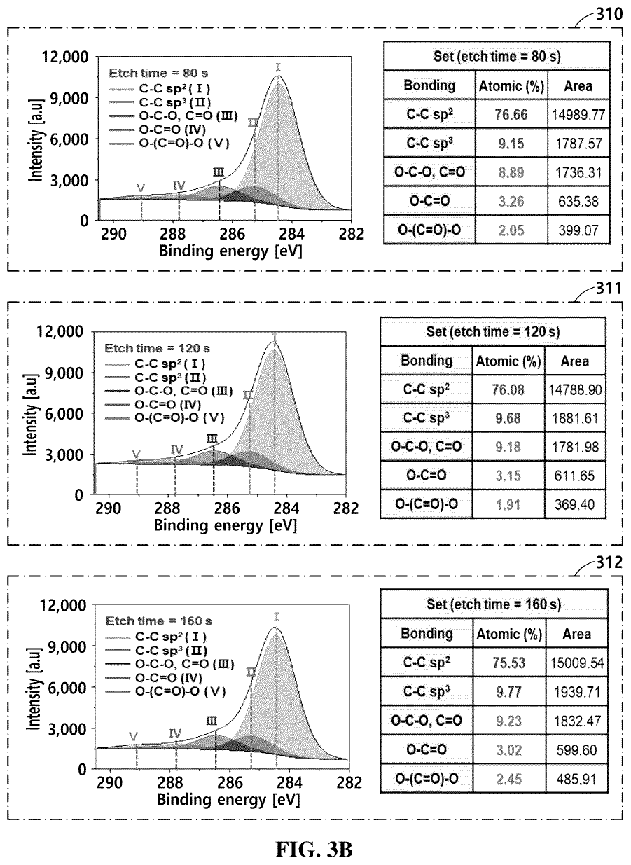

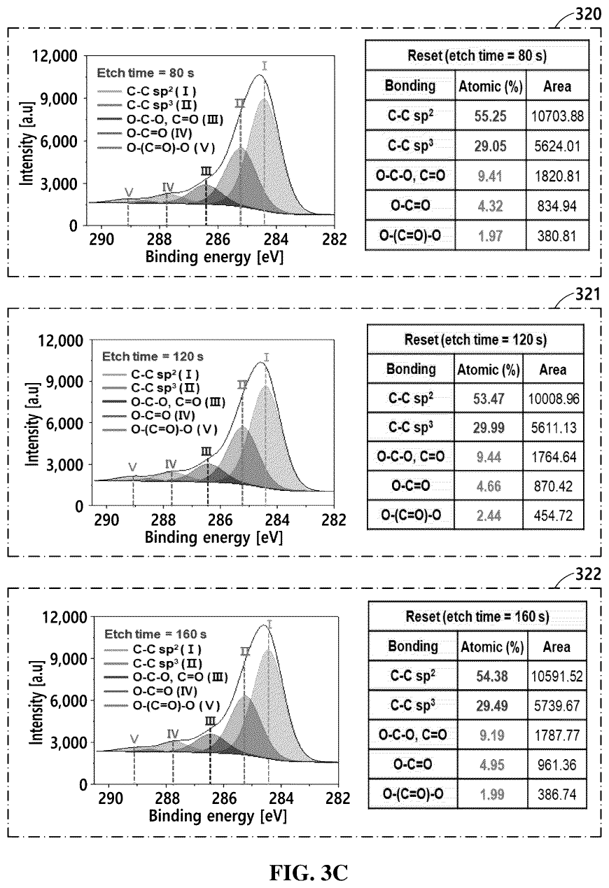

FIGS. 3A to 3C are drawings for explaining XPS C1s peak according to an etching time of the artificial synapse device according to an embodiment of the present invention.

FIGS. 3A to 3C illustrate changes in the coupling state of the C1s peak in the initial state, set state, and reset state inside the switching layer after etching the first electrode while changing an etching time from 80 to 160 seconds such that the artificial synapse device according to an embodiment of the present invention has a 60 μm cell size.

FIG. 3A illustrates changes in a binding state of the C1s peak according to an etching time change in the pristine state of an artificial synapse device according to an embodiment of the present invention.

Referring to FIG. 3A, graph 300 may correspond to an etching time of 80 seconds, graph 301 may correspond to an etching time of 120 seconds, and graph 302 may correspond to an etching time of 160 seconds.

FIG. 3B illustrates changes in the binding state of the C1s peak according to an etching time change in the set state of the artificial synapse device according to an embodiment of the present invention.

Referring to FIG. 3B, graph 310 may correspond to an etching time of 80 seconds, graph 311 may correspond to an etching time of 120 seconds, and graph 312 may correspond to an etching time of 160 seconds.

FIG. 3C illustrates changes in the binding state of the C1s peak according to an etching time change in the reset state of the artificial synapse device according to an embodiment of the present invention.

Referring to FIG. 3C, graph 320 may correspond to an etching time of 80 seconds, graph 321 may correspond to an etching time of 120 seconds, and graph 322 may correspond to an etching time of 160 seconds.

Referring to graphs 310, 311 and 312 of FIG. 3B, a low-resistance state (LRS), i.e., a set state, wherein a (−) voltage corresponding to set voltage is applied to the first electrode, the binding ratio of the first conductive hybrid orbital (C—C sp²) increases as oxygen ions move toward the second electrode, and the second hybrid orbital (C—C sp³) of carbon atoms and the bonding ratio of carbon and oxygen (C—O) are reduced to form a carbon filament corresponding to the first hybrid orbital (C—C sp²), can be confirmed in the set process.

According to an embodiment of the present invention, in the switching layer when a set voltage is applied through the first electrode, oxygen atoms move to the second electrode, increasing the coupling ratio of the first hybrid orbital (C—C sp²) of carbon atoms, and the second hybrid orbital of carbon atoms. (C—C sp³) and the bonding ratio of carbon and oxygen (C—O) decreases, thereby forming filaments of the first hybrid orbital (C—C sp²).

Referring to graphs 1020, 1021 and 1022 of FIG. 3C, a high-resistance state (HRS), i.e., a reset state, wherein a (+) voltage corresponding to reset voltage is applied to a first electrode, the binding ratio of the first hybrid orbital (C—C sp²) decreases as oxygen ions move toward the first electrode, and the second hybrid orbital (C—C) of carbon atoms sp³) and the bonding ratio of carbon and oxygen (C—O) increases, breaking the filament of the first hybrid orbital (C—C sp²), can be confirmed in the reset process.

For example, in the switching layer when reset voltage is applied through the first electrode, oxygen atoms move to the first electrode, reducing the coupling ratio of the first hybrid orbital (C—C sp²) of carbon atoms, and as the bonding ratio of the second hybrid orbital (C—C sp³) of carbon atoms and carbon and oxygen (C—O) increases, the filaments of the first hybrid orbital (C—C sp²) may break near the second electrode.

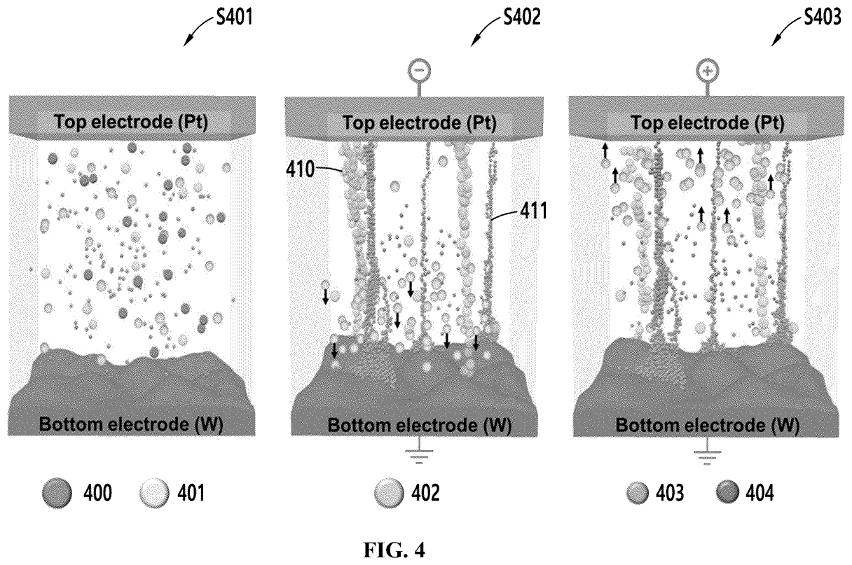

FIG. 4 is a drawing for explaining the switching model of the artificial synapse device according to an embodiment of the present invention.

Referring to FIG. 4, an operation of the artificial synapse device according to an embodiment of the present invention includes a pristine state S401, a set state S402 and a reset state S403.

The pristine state S401, the set state S402 and the reset state S403 show the distribution of oxygen atoms 400, oxygen ions 401, oxygen vacancies 402, first hybrid orbital 403 of carbon atoms and second hybrid orbital 404 of carbon atoms to indicate the operation state of the artificial synapse device.

In the pristine state S401, the oxygen atoms 400, the oxygen ions 401, the oxygen vacancies 402, the first hybrid orbitals 403 of carbon atoms and the second hybrid orbitals 404 of carbon atoms coexist in the switching layer.

In the set state S402, when a set voltage corresponding to a negative voltage is applied through the first electrode corresponding to a platinum (Pt) electrode, and the second electrode corresponding to a tungsten (W) electrode is connected to the ground, the filaments 410 of oxygen vacancies and the filaments 411 of the first hybrid orbitals are formed inside the switching layer so that the artificial synapse device enters a low-resistance state.

According to an embodiment of the present invention, when set voltage is applied to the first electrode, the binding ratio of the first hybrid orbitals (C—C sp²) increases as the oxygen ions 401 move toward the second electrode, and the filaments 410 of oxygen vacancies and the filaments 411 of first hybrid orbitals (C—C sp²) may be formed inside the switching layer as the binding ratio of the second hybrid orbitals (C—C sp³) and the binding ratio of the oxygen atoms 400 and carbon atoms decrease.

After the reset process in which a reset voltage corresponding to a positive voltage is applied, the oxygen atoms 400, the oxygen ions 401, the oxygen vacancies 402, the first hybrid orbitals 403 of carbon atoms and the second hybrid orbitals 404 of carbon atoms are redistributed inside the switching layer so that the filaments 410 of oxygen vacancies and the filaments 411 of the first hybrid orbitals are broken, thereby achieving a reset state S203 corresponding to a high-resistance state.

According to an embodiment of the present invention, when reset voltage is applied to the first electrode, filaments of oxygen vacancies and filaments of first hybrid orbitals (C—C sp²) may be broken as the oxygen ions 401 move toward the first electrode, the binding ratio of the first hybrid orbitals (C—C sp²) decreases, and the binding ratio of the second hybrid orbitals (C—C sp³) and the binding ratio of the oxygen atoms 400 and carbon atoms increase.

FIGS. 5A and 5B are drawings for explaining a process of fabricating the artificial synapse device according to an embodiment of the present invention.

FIG. 5A illustrates an off-axis sputtering process according to an existing technology.

Referring to FIG. 5A, an off-axis sputtering process environment 500 has a structure wherein a gas injector 502 injects oxygen (O₂) and argon (Ar) gases into a process case 501.

In the case 501, a process of depositing carbon 504 through sputtering by applying plasma 505 to a target substrate 507 is performed.

For example, the carbon 504 may be referred to as a carbon target, and a carbon target may be mounted on a sputtering gun 503.

In addition, the substrate 507 may be fixed by a fixing device 506.

For example, in the off-axis sputtering process environment 500, the sputtering gun 503, a plasma 505 and the fixing device 506 are not located on the same axis and the sputtering process is performed, so there is a problem with mass production that it is difficult to mass fabricate an artificial synapse device.

FIG. 5B illustrates an on-axis sputtering process according to an embodiment of the present invention.

Referring to FIG. 5B, an on-axis sputtering process environment 510 has a structure wherein a gas injector 512 injects oxygen (O₂) and argon (Ar) gases to a process case 511.

In the case 511, a process of depositing a carbon 514 on a target substrate 517 through sputtering by applying a plasma 515 is performed.

For example, the carbon 514 may be referred to as a carbon target, and the carbon target may be mounted on a sputtering gun 513.

In addition, the substrate 517 may be fixed by a fixing device 516.

For example, the on-axis sputtering process environment 510 may improve problems related to the mass productivity of an artificial synapse device as the sputtering process is performed with the sputtering gun 513, the plasma 515 and the fixing device 516 located on the same axis.

Process conditions in the on-axis sputtering process environment 510 may be as follows: a sputtering power is DC 250 watts, a working pressure is 1.0×10⁻³ torr, an argon flow rate is 10 sccm, an oxygen flow rate is 0.8 to 1.6 sccm, and an oxygen content is 7.4% to 13.8%.

Here, an oxygen content corresponds to a value obtained by dividing an oxygen flow rate by the sum of an argon flow rate and an oxygen flow rate and then multiplying it by 100.

According to an embodiment of the present invention, the artificial synapse device may ensure gradual switching current and voltage characteristics and corresponding synapse characteristics when the oxygen content is 10.7%.

Accordingly, the switching layer of the artificial synapse device is preferably formed of an amorphous carbon oxide deposited by injecting oxygen in an oxygen content of 10% to 11% based on an on-axis sputtering process when sputtering carbon to a target.

In addition, the present invention may improve the mass productivity of the artificial synapse device by using the on-axis sputtering process.

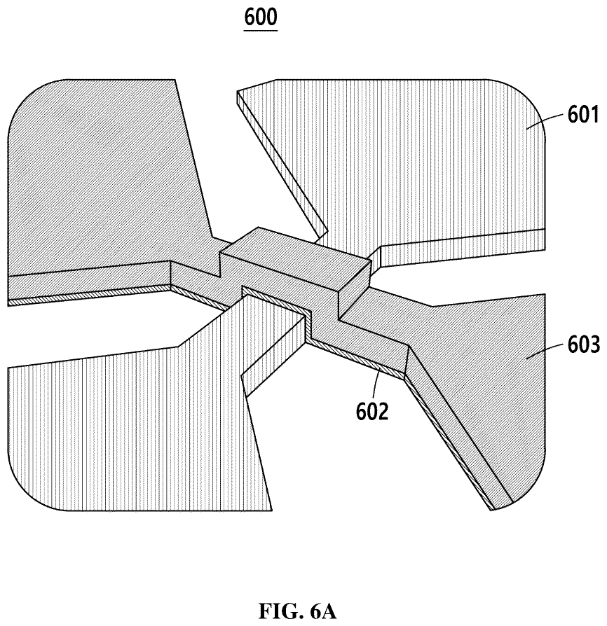

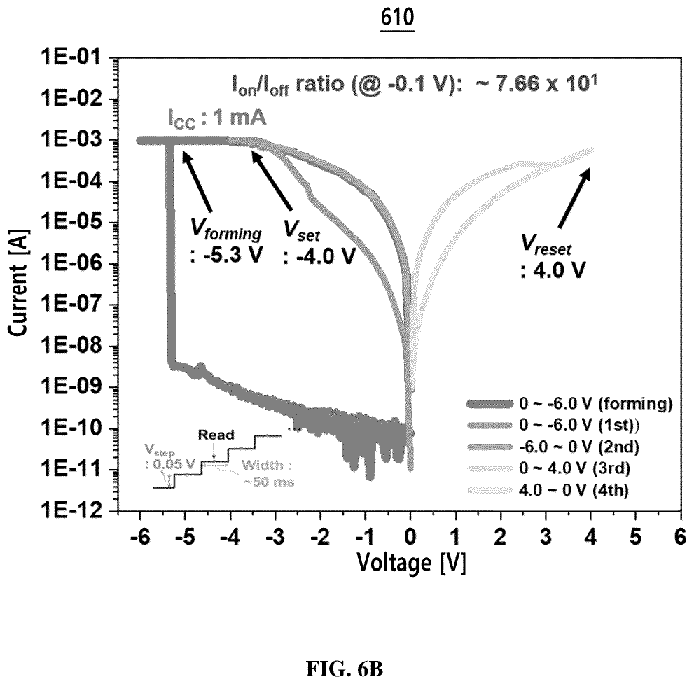

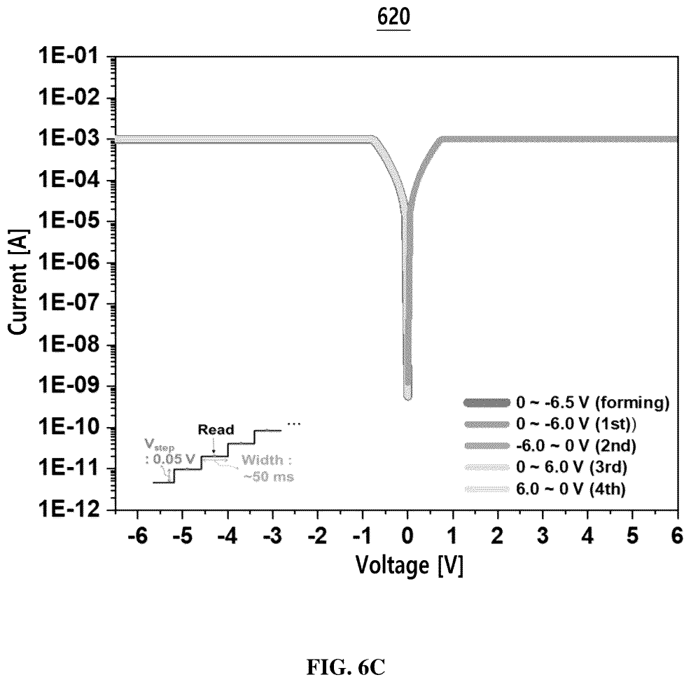

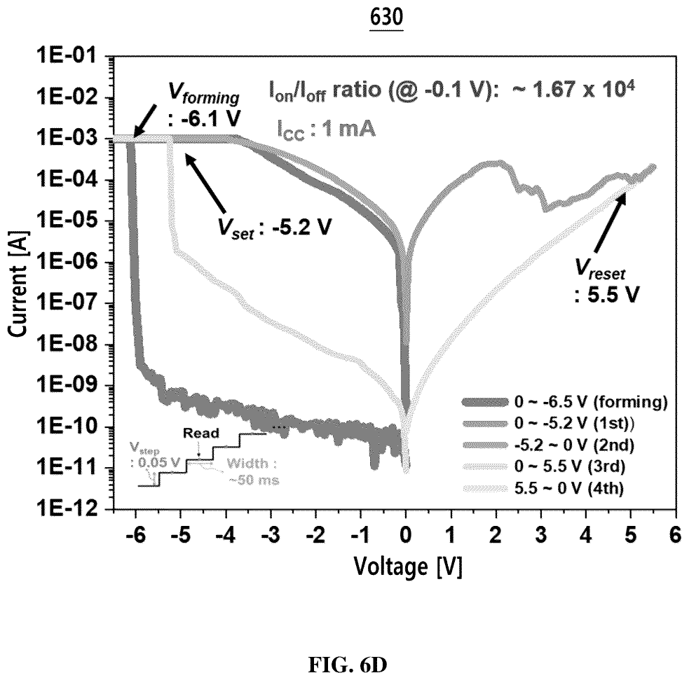

FIG. 6A is a drawing for explaining the crossbar structure of the artificial synapse device according to an embodiment of the present invention.

Referring to FIG. 6A, an artificial synapse device 600 according to an embodiment of the present invention includes a first electrode 603, a switching layer 602 and a second electrode 601.

For example, the artificial synapse device 600 has a cell size of 5 μm and a crossbar shape.

That is, the artificial synapse device 600 has a width of 5 μm in the area where the first electrode 603, the switching layer 602 and the second electrode 601 overlap.

Accordingly, the switching layer 602 may be formed with horizontal and vertical axes of 5 μm.

The first electrode 603 may be formed of platinum (Pt), the second electrode 601 may be formed of tungsten (W), and the switching layer 602 may be formed of an amorphous carbon oxide.

According to an embodiment of the present invention, a bias voltage is applied as a set voltage or a reset voltage to the first electrode 603, and the second electrode 601 is connected to the ground (GND).

For example, the resistance state of the switching layer 602 changes to a set state or reset state based on a set voltage or reset voltage applied through the first electrode 603.

FIGS. 6B to 6D are drawings for explaining the electrical characteristics of the crossbar structure of the artificial synapse device according to an embodiment of the present invention.

FIG. 6B illustrates a forming voltage, set voltage and reset voltage among the electrical characteristics of the crossbar structure of the artificial synapse device according to an embodiment of the present invention.

Referring to FIG. 6B, graph 610 illustrates a forming voltage, set voltage and reset voltage measured according to changes in voltage applied through the first electrode.

Referring to graph 610, it can be confirmed that the forming voltage is −5.3 V, the set voltage is −4.0 V, and the reset voltage is 4.0 V.

It can be confirmed that the set voltage (−4.0 V) and the reset voltage (4.0V) have bidirectional symmetrical current-voltage characteristics.

The bidirectional symmetrical current-voltage characteristics enable the artificial synapse device to secure synaptic characteristics.

According to an embodiment of the present invention, it can be confirmed that the memory margin is 7.66×10¹.

Here, graph 610 shows the measurement results when the oxygen content of an amorphous carbon oxide forming a switching layer is 10.7%, and the process results for the 7.4% and 13.8% cases corresponding to the remaining oxygen content illustrated in FIG. 5B are illustrated in FIGS. 6C and 6D.

FIGS. 6C and 6D show a forming voltage, set voltage and reset voltage among the electrical characteristics of the crossbar structure of an artificial synapse device whose oxygen content is determined differently according to an embodiment of the present invention.

Graph 620 of FIG. 6C illustrates a case where an oxygen content for forming the switching layer of the artificial synapse device is 7.4%, and graph 630 of FIG. 6D illustrates a case where an oxygen content for forming the switching layer of the artificial synapse device is 13.8%.

Referring to graph 620 of FIG. 6C, when the oxygen content for forming the switching layer of the artificial synapse device is 7.4%, a low resistance state is maintained from the pristine state, which may make switching transition difficult.

Referring to graph 630 of FIG. 6D, when the oxygen content for forming the switching layer of an artificial synapse device is 13.8%, it can be confirmed that it has abrupt electrical characteristics.

The forming voltage is −6.1 V, the set voltage is −5.2 V, and the reset voltage is 5.5V, making it difficult to confirm bidirectional symmetrical current-voltage characteristics.

That is, in the case of 7.4% and 13.8% which corresponds to the oxygen content, there is a disadvantage in that it is difficult to secure synaptic characteristics.

FIGS. 7A to 7C are drawings for explaining the paired-pulse facilitation (PPF) characteristics and memory characteristics of the artificial synapse device according to an embodiment of the present invention.

FIGS. 7A and 7B illustrate imitation results of the paired-pulse facilitation (PPF) characteristics of the artificial synapse device according to an embodiment of the present invention.

Referring to graph 700 of FIG. 7A, it can be confirmed that the magnitude of the applied voltage is the same over time, and the magnitude of the measured current changes depending on the applied voltage.

Graph 710 of FIG. 7B shows that, when a voltage level of −3V corresponding to the same voltage level is repeatedly applied to the first electrode of the artificial synapse device at a certain pulse size and regular pulse interval, the current size increases by a certain amount on average.

For example, the characteristics of short-term synaptic plasticity, in which the weight of the synapse gradually increases in the short term, are exhibited when subsequent pulses stimulate it at short time intervals, and thus the function may be implemented through an amorphous carbon oxide-based resistance change memory.

FIG. 7C illustrates the memory characteristics of the artificial synapse device according to an embodiment of the present invention.

Referring to graph 720 of FIG. 7C, the results of experiments of checking a current value after applying 10 and 100 pulses under a condition of each of a pulse width of 50 ms, a voltage amplitude of −3.0 V, and a pulse interval of 10 ms, and rechecking a current value after 180 seconds are shown.

For example, when a total of 10 pulses were applied, the current value increased from about 4.3×10⁻⁵ A to 6.4×10⁻⁵ A, showing short-term memory operation characteristics in which the current value decreases to the initial value after about 180 seconds.

In addition, when a total of 100 pulses were applied, the current value increased from about 4.3×10⁻⁵ A to 1.1×10⁻⁴ A, and the current value after about 180 seconds is almost the same as the current value after applying 100 pulses of 1.0×10⁻⁴ A, which shows long-term memory operation characteristics.

That is, an artificial synapse device may perform one memory operation of a short-term memory operation wherein a current value is reduced to an initial value after a certain time based on the number of times the same voltage is repeatedly applied and a long-term memory operation wherein a current value is maintained after a certain time.

FIGS. 8A and 8B are drawings for explaining the electrical characteristics according to the gradual set or reset process of the artificial synapse device according to an embodiment of the present invention.

FIG. 8A illustrates changes in electrical characteristics when the same set voltage is continuously applied to the first electrode of the artificial synapse device according to an embodiment of the present invention.

FIG. 8B illustrates changes in electrical characteristics when the same reset voltage is continuously applied to the first electrode of the artificial synapse device according to an embodiment of the present invention.

Referring to graph 800 of FIG. 8A, it can be confirmed that, when a set voltage of −2.5 V is swept 32 times in succession in the artificial synapse device according to an embodiment of the present invention, the current gradually increases.

Specifically, it can be confirmed that as the set voltage is continuously applied, the output current tends to gradually increase from −4.54×10⁻⁵ A to −3.97×10⁻⁴ A.

Referring to graph 810 of FIG. 8B, it can be confirmed that, when a reset voltage of 2.2 V is swept 32 times in succession in the artificial synapse device according to an embodiment of the present invention, the current gradually decreases.

Specifically, it can be confirmed that as the reset voltage is continuously applied, the output current tends to gradually decrease from 3.18×10⁻⁴ A to −1.05×10⁻⁴ A.

From graphs 800 and 810, it can be confirmed that the artificial synapse device according to an embodiment of the present invention has a total of 32 conductivity level states through a gradual set and reset process.

For example, the artificial synapse device may have multiple conductivity levels with a gradual increase in an output current value when a set voltage with the same pulse width, pulse interval, and voltage magnitude is repeatedly applied to the first electrode or multiple conductivity levels with a gradual decrease in an output current value when a reset voltage with the same pulse width, pulse interval, and voltage magnitude is repeatedly applied to the first electrode.

Accordingly, Therefore, the present invention may provide an artificial synapse device capable of finely adjusting weights during online learning for Modified National Institute of Standards and Technology (MINIST) handwriting images by securing a plurality of conductance level states.

That is, the present invention may provide an artificial synapse device with multiple conductivity levels corresponding to 32 levels using an amorphous carbon oxide-based resistance change memory device.

FIGS. 9A and 9B are drawings for explaining the synaptic characteristics of the artificial synapse device according to an embodiment of the present invention.

FIG. 9A illustrates the normalized conductance results and synaptic characteristics of 20 cells of the artificial synapse device according to an embodiment of the present invention.

Referring to graph 900 of FIG. 9A, it can be confirmed that the normalized conductance values for 20 cells of the artificial synapse device stably maintain 32 conductance levels.

That is, graph 900 illustrates the result of measuring DC current-voltage gradual switching characteristics for 20 cells to measure the reliability of synapse with 32 levels, and as a result of normalizing the current at −2.5V and plotting the conductivity of all 20 cells, the artificial synapse device can secure very stable 32-level characteristics.

For example, the 20 cells of the artificial synapse device may correspond to an artificial synapse device array consisting of multiple (20) artificial synapse devices.

FIG. 9B illustrates the synaptic characteristics of the artificial synapse device according to an embodiment of the present invention.

Graph 910 of FIG. 9B shows a synapse strengthening characteristic in which a conductance level value gradually increases by continuously applying a potentiation pulse and a read pulse 100 times and a synapse suppression characteristic in which the conductance level gradually decreases by continuously applying a depression pulse and a read pulse 100 times.

Specifically, the strengthening pulse may have a negative voltage of −2.6V and a pulse width of about 1 ms, the suppressing pulse may have a positive voltage of 2.8V, and the lead pulse has the same pulse width of 1 ms and a voltage of −1.0 V.

It can be confirmed that the curve fitting result of reinforcement according to the potentiation pulse has a linearity of 1.236, and the curve fitting result of suppression according to the depression pulse has a linearity of 7.026, and the linearity may be better as it converges to 0.

Here, the curve fitting result of reinforcement may correspond to a long-term reinforcement measurement result, and the curve fitting result of suppression may correspond to a long-term suppression measurement result.

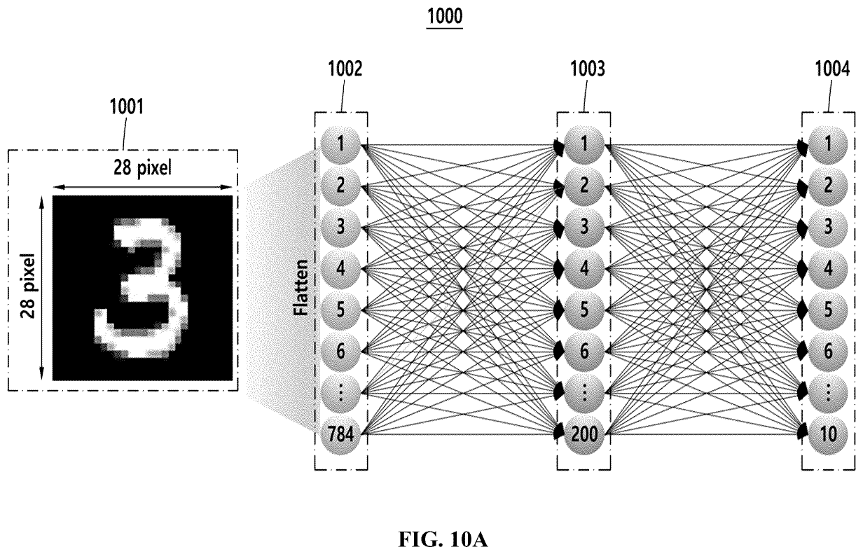

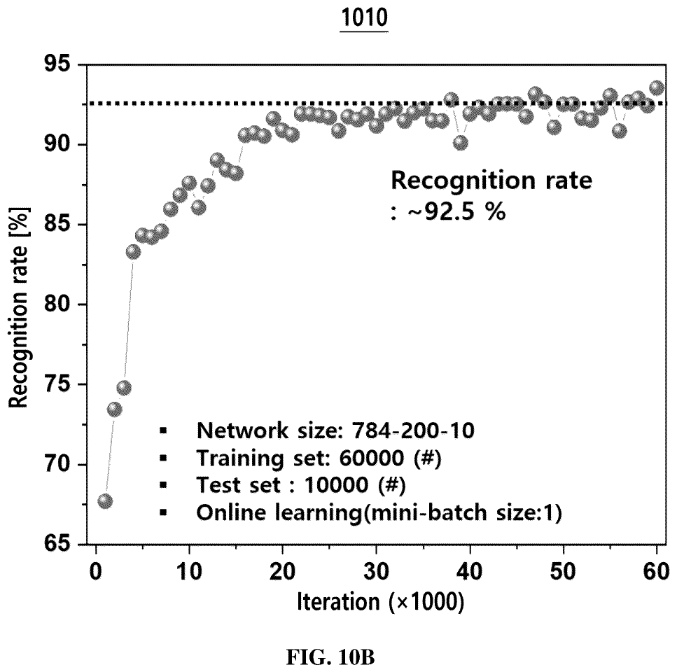

FIGS. 10A and 10B are drawings for explaining an artificial neuron network using the artificial synapse device according to an embodiment of the present invention and the recognition rate of the artificial neuron network.

FIG. 10A illustrates an artificial neuron network using the artificial synapse device according to an embodiment of the present invention.

Referring to FIG. 10A, an artificial neuron network 1000 using the artificial synapse device according to an embodiment of the present invention trains a recognition object 1001 through an input layer 1002, a hidden layer 1003 and an output layer 1004.

For example, the artificial neuron network 1000 using the artificial synapse device uses 784 artificial neurons in the input layer 1002, 200 artificial neurons in the hidden layer 1003, and 10 artificial neurons in the output layer 1004 for Modified National Institute of Standards and Technology (MNIST) handwriting image classification simulation.

A training set of handwriting images may contain 60,000 pieces of data, and the test set may contain 10,000 pieces of data.

Since it is implemented in hardware and the conductance of the artificial synapse device is updated in real-time, online learning is assumed on simulation (mini-batch size: 1 unit).

Since the learning rule is a simulation of assuming that back-propagation may be used and it is implemented in hardware, a neural network may be learned by updating the conductance of connected synaptic elements step by step through the sign of an error rather than using an actual differential value.

FIG. 10B illustrates the learning results of an artificial neuron network using the artificial synapse device according to an embodiment of the present invention.

Referring to graph 1010 of FIG. 10B, it can be confirmed that the handwriting image recognition rate indicates accuracy for 10,000 pieces of data in the test set, and after learning approximately 20,000 pieces of training data through simulation results, the recognition rate for the test set is 92.5% or more.

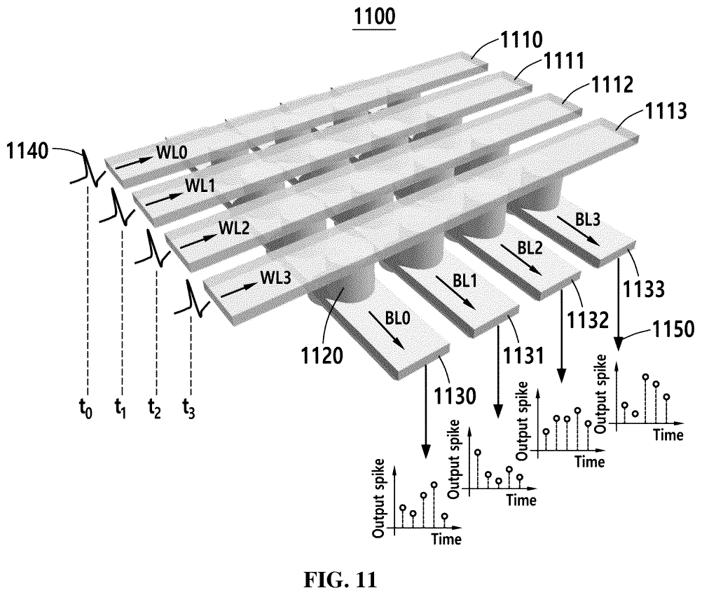

FIG. 11 illustrates a drawing for explaining an artificial synapse device array using a plurality of artificial synapse devices according to an embodiment of the present invention.

FIG. 11 illustrates an artificial synapse device array including the plural artificial synapse devices according to an embodiment of the present invention.

Referring to FIG. 11, the artificial synapse device array using the plural artificial synapse devices according to an embodiment of the present invention has a structure wherein an artificial synapse device is included between a word line and a bit line.

In the case of 4×4, the artificial synapse device array 1100 using the plural artificial synapse devices according to an embodiment of the present invention may include a first word line 1110, second word line 1111, third word line 1113, and fourth word line 1114 as word lines, and a first bit line 1130, second bit line 1131, third bit line 1133, and fourth bit line 1134 as bit lines.

For example, the artificial synapse devices 1120 may operate in the same manner as the artificial synapse device illustrated in FIG. 1 and the like.

An artificial synapse device array 1100 using the plural artificial synapse devices may receive an input 1140 at different times from the first word line 1110, the second word line 1111, the third word line 1113, the fourth word line 1114 and may output different outputs 1150 through the first bit line 1130, the second bit line 1131, the third bit line 1133, the fourth bit line 1134.

For example, the input 1140 may be an input spike signal, and the output 1150 may be an output spike signal.

According to an embodiment of the present invention, the artificial synapse devices 1120 may have synaptic characteristics wherein the value of the output current changes gradually when the same voltage of either set voltage or reset voltage is repeatedly applied to the first electrode through each of the plural word lines.

In addition, the artificial synapse devices 1120 may have multiple conductivity levels as the value of the output current gradually increases when a set voltage with the same pulse width, pulse interval, and voltage magnitude is repeatedly applied to the first electrode through each of the plural word lines.

In addition, the artificial synapse devices 1120 may have multiple conductivity levels as the value of the output current gradually reduces when a reset voltage with the same pulse width, pulse interval, and voltage magnitude is repeatedly applied to the first electrode through each of the plural word lines.

Accordingly, the present invention may provide an artificial synapse device array using a plurality of artificial synapse devices that maintain a plurality of conductivity level states corresponding to 32 levels using the plural resistance change memory devices based on an amorphous carbon oxide.

Although the present invention has been described with reference to limited embodiments and drawings, it should be understood by those skilled in the art that various changes and modifications may be made therein. For example, the described techniques may be performed in a different order than the described methods, and/or components of the described systems, structures, devices, circuits, etc., may be combined in a manner that is different from the described method, or appropriate results may be achieved even if replaced by other components or equivalents.

Therefore, other embodiments, other examples, and equivalents to the claims are within the scope of the following claims.

1. An artificial synapse device, comprising:
a first electrode;
a second electrode disposed to face the first electrode; and
a switching layer formed of an amorphous carbon oxide deposited by injecting oxygen when sputtering carbon into a target between the first electrode and the second electrode,
wherein the artificial synapse device has synaptic characteristics wherein a value of an output current changes gradually when a same voltage of either set voltage or reset voltage is repeatedly applied to the first electrode.

2. The artificial synapse device according to claim 1, wherein the artificial synapse device has multiple conductivity levels as the value of the output current gradually increases when a set voltage with a same pulse width, pulse interval, and voltage magnitude is repeatedly applied to the first electrode.

3. The artificial synapse device according to claim 1, wherein the artificial synapse device has multiple conductivity levels as the value of the output current gradually reduces when a reset voltage with a same pulse width, pulse interval, and voltage magnitude is repeatedly applied to the first electrode.

4. The artificial synapse device according to claim 1, wherein the artificial synapse device performs one memory operation of a short-term memory operation wherein a current value is reduced to an initial value after a certain time based on the number of times the same voltage is repeatedly applied and a long-term memory operation wherein the current value is maintained after the certain time.

5. The artificial synapse device according to claim 1, wherein the switching layer is formed of the amorphous carbon oxide deposited by injecting oxygen in an oxygen content of 10% to 11% based on an on-axis sputtering process when sputtering the carbon to a target.

6. The artificial synapse device according to claim 1, wherein oxygen atoms, oxygen ions, oxygen vacancies, first hybrid orbitals (C—C sp²) of carbon atoms and second hybrid orbitals (C—C sp³) of carbon atoms coexist in a pristine state of the switching layer, and, when the set voltage is applied to the first electrode, filaments of oxygen vacancies and filaments of first hybrid orbitals (C—C sp²) are formed between the first electrode and the second electrode, thereby becoming a set state of a low-resistance state (LRS).

7. The artificial synapse device according to claim 6, wherein in the switching layer when the set voltage is applied to the first electrode, a binding ratio of the first hybrid orbitals (C—C sp²) increases while the oxygen ions move toward the second electrode, and filaments of the oxygen vacancies and filaments of the first hybrid orbitals (C—C sp²) are formed as a binding ratio of the second hybrid orbitals (C—C sp³) and a binding ratio of the oxygen atoms and the carbon atoms decrease.

8. The artificial synapse device according to claim 6, wherein, in the switching layer when the reset voltage is applied to the first electrode in the set state, the filaments of the oxygen vacancies and the filaments of the first hybrid orbitals (C—C sp²) between the first electrode and the second electrode are broken, becoming a reset state of a high-resistance state (HRS).

9. The artificial synapse device according to claim 8, wherein, in the switching layer when the reset voltage is applied to the first electrode, the filaments of the oxygen vacancies and the filaments of the first hybrid orbitals (C—C sp²) are broken as the oxygen ions move toward the first electrode, the binding ratio of the first hybrid orbitals (C—C sp²) decreases, and the binding ratio of the second hybrid orbitals (C—C sp³) and the binding ratio of the oxygen atoms and the carbon atoms increase.

10. The artificial synapse device according to claim 1, wherein the first electrode and the second electrode is formed of at least one metal material selected from platinum (Pt), tungsten (W), titanium nitride (TiN), tantalum nitride (TaN), gold (Au), rubidium (Ru), iridium (Ir), palladium (Pd), titanium (Ti), hafnium (Hf), molybdenum (Mo) and niobium (Nb).

11. A method of fabricating an artificial synapse device, the method comprising:
forming a second electrode on a substrate,
forming a switching layer with an amorphous carbon oxide deposited by injecting oxygen when sputtering carbon to a target on the second electrode, and
forming a first electrode on the switching layer to form the artificial synapse device,
the artificial synapse device has synaptic characteristics wherein a value of an output current changes gradually when a same voltage of either set voltage or reset voltage is repeatedly applied to the first electrode.

12. The method according to claim 11, wherein the artificial synapse device has multiple conductivity levels as the output current value gradually increases when a set voltage with a same pulse width, pulse interval, and voltage magnitude is repeatedly applied to the first electrode or multiple conductivity levels as the output current value gradually reduces when a reset voltage with a same pulse width, pulse interval, and voltage magnitude is repeatedly applied to the first electrode, and
the artificial synapse device performs one memory operation of a short-term memory operation wherein a current value is reduced to an initial value after a certain time based on the number of times the same voltage is repeatedly applied and a long-term memory operation wherein the current value is maintained after the certain time.

13. The method according to claim 11, wherein the forming of the switching layer includes forming a switching layer with the amorphous carbon oxide deposited by injecting oxygen in an oxygen content of 10% to 11% based on an on-axis sputtering process when sputtering the carbon to the target.

14. An artificial synapse device array, comprising:
a plurality of artificial synapse devices, each of the artificial synapse devices comprising a first electrode, a second electrode disposed to face the first electrode, and a switching layer formed of an amorphous carbon oxide deposited by injecting oxygen when sputtering carbon to a target between the second electrode;
a plurality of word lines connected to a first electrode of each of the plural artificial synapse devices; and
a plurality of bit lines connected to a second electrode of each of the plural artificial synapse devices,
wherein each of the plural artificial synapse devices has synaptic characteristics wherein a value of an output current changes gradually when a same voltage of either set voltage or reset voltage is repeatedly applied to the first electrode through each of the plural word lines.

15. The artificial synapse device array according to claim 14, wherein each of the artificial synapse devices has multiple conductivity levels as the value of the output current gradually increases when a set voltage with a same pulse width, pulse interval, and voltage magnitude is repeatedly applied to the first electrode through each of the plural word lines or multiple conductivity levels as the value of the output current gradually reduces when a reset voltage with a same pulse width, pulse interval, and voltage magnitude is repeatedly applied to the first electrode through each of the plural word lines.
